(19) United States
(12) Patent Application Publication
(10) Pub. No.: US 2024/0193109 A1
(43) Pub. Date: Jun. 13, 2024

(54) APPARATUS AND METHOD TO REDUCE MEMORY POWER CONSUMPTION IN A MEMORY PHY IN A MEMORY CONTROLLER

(71) Applicant: Intel Corporation, Santa Clara, CA (US)

(72) Inventors: Michelle M. WIGTON, Timnath, CO (US); Kambiz R. MUNSHI, Westford, MA (US); Zhongyao Linda GU, Acton, MA (US); Mohammad M. RASHID, San Jose, CA (US); Victor LAU, Marlborough, MA (US); Jing LING, Milpitas, CA (US)

(21) Appl. No.: 18/444,379

(22) Filed: Feb. 16, 2024

(51) Int. Cl. G06F 13/16; H10B 12/00

(52) U.S. Cl. CPC G06F 13/1689; H10B 12/00

(57) ABSTRACT

Memory power consumption is reduced without increasing latency of memory read access. When inactive, power consumption is reduced in a PHY in a memory controller by disabling receiver bias circuitry and a clock network in the PHY. The memory controller sends two command-based signals to the PHY to enable the PHY to enable the receiver bias circuitry and the clock network in the PHY to transition the memory from a low power state to an active power state prior to or at the time of receiving command from the memory controller. A first command-based signal is an early command indication signal that is sent before any command. The second command-based signal is a read indication signal that is sent synchronous with every read command. Upon receiving these signals, the PHY enables the clock network and receiver bias circuitry.

### FIELD

This disclosure relates to memory power consumption and in particular to reducing memory power consumption in a memory PHY in a memory controller without increasing latency of memory read access.

### BACKGROUND

Traditionally, computer systems have different memory subsystem power management states. With the different power management states, memory power consumption tends to be inversely proportional to transition time from a low power state to an active power state. For example, a memory subsystem can have four power states, for example, active idle power, memory power down (analog clock components powered down), memory self-refresh, and low power state (PLL (phase locked loop) and voltage rails powered down). The low power state saves more power, however the exit latency is too long for many workloads to use effectively because the exit latency would have a noticeable performance impact and poor user experience.

### BRIEF DESCRIPTION OF THE DRAWINGS

Features of embodiments of the claimed subject matter will become apparent as the following detailed description proceeds, and upon reference to the drawings, in which like numerals depict like parts, and in which:

FIG. 1 is a block diagram of an example of a memory subsystem to reduce power consumption in a memory PHY without an increase in latency of memory read access;

FIG. 2 is a block diagram of an example of a system in which memory power consumption in the memory PHY is reduced without increasing latency of memory read access;

FIG. 3 is a block diagram of an example of the command clock gating circuitry and the RXBias gating circuitry in the memory PHY;

FIG. 4 is a timing diagram illustrating the operation of the commend clock gating circuitry and the RXBias gating circuitry in the memory PHY; and

FIG. 5 is a block diagram of an embodiment of a computer system that includes the memory PHY.

Although the following Detailed Description will proceed with reference being made to illustrative embodiments of the claimed subject matter, many alternatives, modifications, and variations thereof will be apparent to those skilled in the art. Accordingly, it is intended that the claimed subject matter be viewed broadly, and be defined as set forth in the accompanying claims.

### DETAILED DESCRIPTION

A Dynamic Random Access Memory (DRAM) is controlled by a clock enable (CKE) signal. Input buffers in the DRAM are disabled when the CKE signal is set to a logic ‘0’(off). When the CKE signal is set to logic ‘1’ (on), the input buffers are enabled and propagate command/address signals received from a memory controller to logic/decoders in the DRAM.

While the CKE signal is off, the internal DRAM clock is disabled and power consumption in the DRAM is reduced. A memory controller can put the DRAM into a low power state after memory traffic idleness is detected and the DRAM is in a low power state.

A processor can support different types of power-down modes, for example, active power-down (APD) mode and pre-charged power down (PPD) mode. APD mode is entered if there are open pages in the DRAM when the CKE signal is de-asserted (set to a logic ‘0’ (off)). PPD mode is entered if all banks in the DRAM are pre-charged when the CKE signal is deasserted (set to a logic ‘0’ (off)).

The power savings in PPD mode is greater than in APD mode. However, the exit latency time from both APD mode and PPD mode is too long for workloads that are sensitive to variable and long read latency times.

Memory power consumption is reduced without increasing latency of memory read access. When inactive, power consumption is reduced in the PHY by turning the receiver bias circuitry off and turning off the clock with an early command indication signal. The bias to a Receiver Analog Front End (RX AFE) in the receiver bias circuitry in the PHY and the clock to a Transmitter Analog Front End (TX AFE) in command clock gating circuitry in the PHY are turned off, thereby reducing power consumption in the PHY.

The memory controller sends two command-based signals to the PHY to enable the PHY to enable the receiver bias circuitry and the clock network in the PHY to transition the memory from a low power state to an active power state prior to or at the time of receiving command from the memory controller. A first command-based signal is an early command indication signal that is sent before any command. The second command-based signal is a read indication signal that is sent synchronous with every read command. Upon receiving these signals, the PHY enables the clock network and receiver bias circuitry. In an embodiment with 16 channels of DRAM and a 2:1 Read to Write Memory bandwidth mix, the expected power savings is about 2.25 Watts.

Various embodiments and aspects of the inventions will be described with reference to details discussed below, and the accompanying drawings will illustrate the various embodiments. The following description and drawings are illustrative of the invention and are not to be construed as limiting the invention. Numerous specific details are described to provide a thorough understanding of various embodiments of the present invention. However, in certain instances, well-known or conventional details are not described in order to provide a concise discussion of embodiments of the present inventions.

Reference in the specification to “one embodiment” or “an embodiment” means that a particular feature, structure, or characteristic described in conjunction with the embodiment can be included in at least one embodiment of the invention. The appearances of the phrase “in one embodiment” in various places in the specification do not necessarily all refer to the same embodiment.

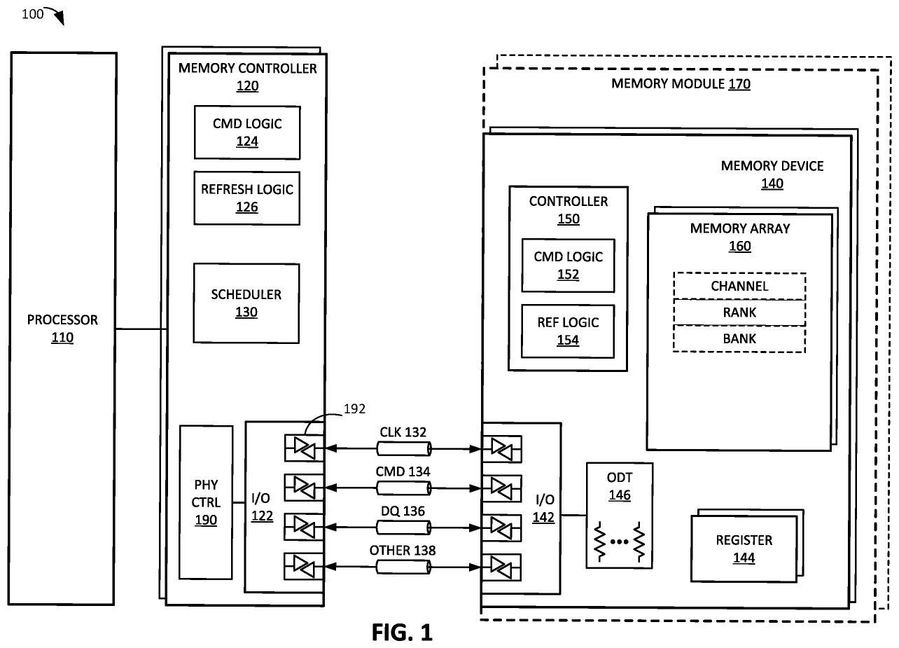

FIG. 1 is a block diagram of an example of a memory subsystem to reduce power consumption in a memory PHY without an increase in latency of memory read access.

System 100 includes a processor 110 and elements of a memory subsystem in a computing device. In one example, system 100 includes PHY control (CTRL) 190 in memory controller 120. PHY control 190 manages the physical interface between memory controller 120 and memory device 140. The physical interface includes I/O interface logic 122 to couple to a memory bus.

Processor 110 represents a processing unit of a computing platform that may execute an operating system (OS) and applications, which can collectively be referred to as the host or the user of the memory. The OS and applications execute operations that result in memory accesses. Processor 110 can include one or more separate processors. Each separate processor can include a single processing unit, a multicore processing unit, or a combination. The processing unit can be a primary processor such as a CPU (central processing unit), a peripheral processor such as a GPU (graphics processing unit), or a combination. Memory accesses may also be initiated by devices such as a network controller or hard disk controller. Such devices can be integrated with the processor in some systems or attached to the processer via a bus (e.g., PCIe (Peripheral Component Interconnect Express), or a combination. System 100 can be implemented as an SOC (system on a chip), or be implemented with standalone components.

Reference to memory devices can apply to different memory types. Memory devices often refers to volatile memory technologies. Volatile memory is memory whose state (and therefore the data stored in it) is indeterminate if power is interrupted to the device. Dynamic volatile memory requires refreshing the data stored in the device to maintain state. One example of dynamic volatile memory includes DRAM (Dynamic Random Access Memory), or some variant such as Synchronous DRAM (SDRAM). A memory subsystem as described herein may be compatible with a number of memory technologies, such as DDR3 (Double Data Rate version 3) JESD79-3F, originally published by JEDEC (Joint Electronic Device Engineering Council) in June 2007. DDR4 (DDR version 4), JESD209-4D, originally published in September 2012, DDR5 (DDR version 5), JESD79-5B, originally published in June 2021, DDR6 (DDR version 6), currently in discussion by JEDEC, LPDDR3 (Low Power DDR version 3, JESD209-3C, originally published in August 2015, LPDDR4 (LPDDR version 4, JESD209-4D, originally published in June 2021), LPDDR5 (LPDDR version 5, JESD209-5B, originally published in June 2021), WIO2 (Wide Input/Output version 2), JESD229-2, originally published in August 2014, HBM (High Bandwidth Memory), JESD235B, originally published in December 2018, HBM2 (HBM version 2, JESD235D, originally published in March 2021, HBM3 (HBM version 3), JESD238A originally published in January 2023) or HBM4 (HBM version 4), currently in discussion by JEDEC, or others or combinations of memory technologies, and technologies based on derivatives or extensions of such specifications. The JEDEC standards are available at www.jedec.org.

Memory controller 120 represents one or more memory controller circuits or devices for system 100. In one example, memory controller 120 is on the same semiconductor substrate as processor 110. Memory controller 120 represents control logic that generates memory access commands in response to the execution of operations by processor 110. Memory controller 120 accesses one or more memory devices 140. Memory devices 140 can be DRAM devices in accordance with any referred to above. In one example, memory devices 140 are organized and managed as different channels, where each channel couples to buses and signal lines that couple to multiple memory devices in parallel. Each channel is independently operable. Thus, each channel is independently accessed and controlled, and the timing, data transfer, command and address exchanges, and other operations are separate for each channel. Coupling can refer to an electrical coupling, communicative coupling, physical coupling, or a combination of these. Physical coupling can include direct contact. Electrical coupling includes an interface or interconnection that allows electrical flow between components, or allows signaling between components, or both. Communicative coupling includes connections, including wired or wireless, that enable components to exchange data.

In one example, settings for each channel are controlled by separate mode registers or other register settings. In one example, each memory controller 120 manages a separate memory channel, although system 100 can be configured to have multiple channels managed by a single controller, or to have multiple controllers on a single channel. In one example, memory controller 120 is part of host processor 110, such as logic implemented on the same die or implemented in the same package space as the processor 110.

Memory controller 120 includes I/O interface logic 122 (physical interface) to couple to a memory bus, such as a memory channel as referred to above. I/O interface logic 122 (as well as I/O interface logic 142 of memory device 140) can include pins, pads, connectors, signal lines, traces, or wires, or other hardware to connect the devices, or a combination of these. I/O interface logic 122 can include a hardware interface. As illustrated, I/O interface logic 122 includes at least drivers/transceivers 192 for signal lines. Commonly, wires within an integrated circuit interface couple with a pad, pin, or connector to interface signal lines or traces or other wires between devices. I/O interface logic 122 can include drivers, receivers, transceivers, or termination, or other circuitry or combinations of circuitry to exchange signals on the signal lines between the devices. The exchange of signals includes at least one of transmit or receive. While shown as coupling I/O 122 from memory controller 120 to I/O 142 of memory device 140, it will be understood that in an implementation of system 100 where groups of memory devices 140 are accessed in parallel, multiple memory devices can include I/O interfaces to the same interface of memory controller 120. In an implementation of system 100 including one or more memory modules 170, I/O 142 can include interface hardware of the memory module in addition to interface hardware on the memory device itself. Other memory controllers 120 will include separate interfaces to other memory devices 140.

The bus between memory controller 120 and memory devices 140 can be implemented as multiple signal lines coupling the memory controller 120 to memory devices 140. The bus may typically include at least clock (CLK) 132, command/address (CMD) 134, data (DQ) 136, and zero or more other signal lines 138. In one example, a bus or connection between memory controller 120 and memory can be referred to as a memory bus. In one example, the memory bus is a multi-drop bus. The signal lines for CMD can be referred to as a “C/A bus” (or ADD/CMD bus, or some other designation indicating the transfer of commands (C or CMD) and address (A or ADD) information) and the signal lines for write and read DQ can be referred to as a “data bus.” In one example, independent channels have different clock signals, C/A buses, data buses, and other signal lines. Thus, system 100 can be considered to have multiple “buses,” in the sense that an independent interface path can be considered a separate bus. It will be understood that in addition to the lines explicitly shown, a bus can include at least one of strobe signaling lines, alert lines, auxiliary lines, or other signal lines, or a combination. It will also be understood that serial bus technologies can be used for the connection between memory controller 120 and memory devices 140. An example of a serial bus technology is 8B10B encoding and transmission of high-speed data with embedded clock over a single differential pair of signals in each direction. In one example, CMD 134 represents signal lines shared in parallel with multiple memory devices. In one example, multiple memory devices share encoding command signal lines of CMD 134, and cach has a separate chip select (CS_n) signal line to select individual memory devices.

It will be understood that in the example of system 100, the bus between memory controller 120 and memory devices 140 includes a subsidiary command bus CMD 134 and a subsidiary bus to carry the write and read data, DQ 136. In one example, the data bus can include bidirectional lines for read data and for write/command data. In another example, the subsidiary bus DQ 136 can include unidirectional write signal lines for write and data from the host to memory, and can include unidirectional lines for read data from the memory to the host. In accordance with the chosen memory technology and system design, other signals 138 may accompany a bus or sub bus, such as strobe lines DQS. Based on design of system 100, or implementation if a design supports multiple implementations, the data bus can have more or less bandwidth per memory device 140. For example, the data bus can support memory devices that have either a ×4 interface, a ×8 interface, a ×16 interface, or other interface. The convention “×W,” where W is an integer that refers to an interface size or width of the interface of memory device 140, which represents a number of signal lines to exchange data with memory controller 120. The interface size of the memory devices is a controlling factor on how many memory devices can be used concurrently per channel in system 100 or coupled in parallel to the same signal lines. In one example, high bandwidth memory devices, wide interface devices, or stacked memory configurations, or combinations, can enable wider interfaces, such as a ×128 interface, a ×256 interface, a ×512 interface, a ×1024 interface, or other data bus interface width.

In one example, memory devices 140 and memory controller 120 exchange data over the data bus in a burst, or a sequence of consecutive data transfers. The burst corresponds to a number of transfer cycles, which is related to a bus frequency. In one example, the transfer cycle can be a whole clock cycle for transfers occurring on a same clock or strobe signal edge (e.g., on the rising edge). In one example, every clock cycle, referring to a cycle of the system clock, is separated into multiple unit intervals (UIs), where each UI is a transfer cycle. For example, double data rate transfers trigger on both edges of the clock signal (e.g., rising and falling). A burst can last for a configured number of UIs, which can be a configuration stored in a register, or triggered on the fly. For example, a sequence of eight consecutive transfer periods can be considered a burst length eight (BL8), and each memory device 140 can transfer data on each UI. Thus, a ×8 memory device operating on BL8 can transfer 64 bits of data (8 data signal lines times 8 data bits transferred per line over the burst). It will be understood that this simple example is merely an illustration and is not limiting.

Memory devices 140 represent memory resources for system 100. In one example, cach memory device 140 is a separate memory die. In one example, cach memory device 140 can interface with multiple (e.g., 2) channels per device or die. Each memory device 140 includes I/O interface logic 142, which has a bandwidth determined by the implementation of the device (e.g., ×16 or ×8 or some other interface bandwidth). I/O interface logic 142 enables the memory devices to interface with memory controller 120. I/O interface logic 142 can include a hardware interface, and can be in accordance with I/O 122 of memory controller, but at the memory device end. In one example, multiple memory devices 140 are connected in parallel to the same command and data buses. In another example, multiple memory devices 140 are connected in parallel to the same command bus, and are connected to different data buses. For example, system 100 can be configured with multiple memory devices 140 coupled in parallel, with each memory device responding to a command, and accessing memory resources 160 internal to cach. For a Write operation, an individual memory device 140 can write a portion of the overall data word, and for a Read operation, an individual memory device 140 can fetch a portion of the overall data word. The remaining bits of the word will be provided or received by other memory devices in parallel.

In one example, memory devices 140 are disposed directly on a motherboard or host system platform (e.g., a PCB (printed circuit board) or substrate on which processor 110 is disposed) of a computing device. In one example, memory devices 140 can be organized into memory modules 170. In one example, memory modules 170 represent dual inline memory modules (DIMMs). In one example, memory modules 170 represent other organization of multiple memory devices to share at least a portion of access or control circuitry, which can be a separate circuit, a separate device, or a separate board from the host system platform. Memory modules 170 can include multiple memory devices 140, and the memory modules can include support for multiple separate channels to the included memory devices disposed on them. In another example, memory devices 140 may be incorporated into the same package as memory controller 120, such as by techniques such as multi-chip-module (MCM), package-on-package, through-silicon via (TSV), or other techniques or combinations. Similarly, in one example, multiple memory devices 140 may be incorporated into memory modules 170, which themselves may be incorporated into the same package as memory controller 120. It will be appreciated that for these and other implementations, memory controller 120 may be part of host processor 110.

Memory devices 140 each include one or more memory arrays 160. Memory array 160 represents addressable memory locations or storage locations for data. Typically, memory array 160 is managed as rows of data, accessed via wordline (rows) and bitline (individual bits within a row) control. Memory array 160 can be organized as separate channels, ranks, and banks of memory. Channels may refer to independent control paths to storage locations within memory devices 140. Ranks may refer to common locations across multiple memory devices (e.g., same row addresses within different devices) in parallel. Banks may refer to sub-arrays of memory locations within a memory device 140. In one example, banks of memory are divided into sub-banks with at least a portion of shared circuitry (e.g., drivers, signal lines, control logic) for the sub-banks, allowing separate addressing and access. It will be understood that channels, ranks, banks, sub-banks, bank groups, or other organizations of the memory locations, and combinations of the organizations, can overlap in their application to physical resources. For example, the same physical memory locations can be accessed over a specific channel as a specific bank, which can also belong to a rank. Thus, the organization of memory resources will be understood in an inclusive, rather than exclusive, manner.

In one example, memory devices 140 include one or more registers 144. Register 144 represents one or more storage devices or storage locations that provide configuration or settings for the operation of the memory device. In one example, register 144 can provide a storage location for memory device 140 to store data for access by memory controller 120 as part of a control or management operation. In one example, register 144 includes one or more Mode Registers. In one example, register 144 includes one or more multipurpose registers. The configuration of locations within register 144 can configure memory device 140 to operate in different “modes,” where command information can trigger different operations within memory device 140 based on the mode. Additionally or in the alternative, different modes can also trigger different operation from address information or other signal lines depending on the mode. Settings of register 144 can indicate configuration for I/O settings (e.g., timing, termination or ODT (on-die termination) 146, driver configuration, or other I/O settings).

In one example, memory device 140 includes ODT 146 as part of the interface hardware associated with I/O 142. ODT 146 can be configured as mentioned above, and provide settings for impedance to be applied to the interface to specified signal lines. In one example, ODT 146 is applied to DQ signal lines. In one example, ODT 146 is applied to command signal lines. In one example, ODT 146 is applied to address signal lines. In one example, ODT 146 can be applied to any combination of the preceding. The ODT settings can be changed based on whether a memory device is a selected target of an access operation or a non-target device. ODT 146 settings can affect the timing and reflections of signaling on the terminated lines. Careful control over ODT 146 can enable higher-speed operation with improved matching of applied impedance and loading. ODT 146 can be applied to specific signal lines of I/O interface 142, 122 (for example, ODT for DQ lines or ODT for CA lines), and is not necessarily applied to all signal lines.

Memory device 140 includes controller 150, which represents control logic within the memory device to control internal operations within the memory device. For example, controller 150 decodes commands sent by memory controller 120 and generates internal operations to execute or satisfy the commands. Controller 150 can be referred to as an internal controller, and is separate from memory controller 120 of the host. Controller 150 can determine what mode is selected based on register 144, and configure the internal execution of operations for access to memory resources 160 or other operations based on the selected mode. Controller 150 generates control signals to control the routing of bits within memory device 140 to provide a proper interface for the selected mode and direct a command to the proper memory locations or addresses. Controller 150 includes command logic 152, which can decode command encoding received on command and address signal lines. Thus, command logic 152 can be or include a command decoder. With command logic 152, memory device can identify commands and generate internal operations to execute requested commands.

Referring again to memory controller 120, memory controller 120 includes command (CMD) logic 124, which represents logic or circuitry to generate commands to send to memory devices 140. The generation of the commands can refer to the command prior to scheduling, or the preparation of queued commands ready to be sent. Generally, the signaling in memory subsystems includes address information within or accompanying the command to indicate or select one or more memory locations where the memory devices should execute the command. In response to scheduling of transactions for memory device 140, memory controller 120 can issue commands via I/O 122 to cause memory device 140 to execute the commands. In one example, controller 150 of memory device 140 receives and decodes command and address information received via I/O 142 from memory controller 120. Based on the received command and address information, controller 150 can control the timing of operations of the logic and circuitry within memory device 140 to execute the commands. Controller 150 is responsible for compliance with standards or specifications within memory device 140, such as timing and signaling requirements. Memory controller 120 can implement compliance with standards or specifications by access scheduling and control.

Memory controller 120 includes scheduler 130, which represents logic or circuitry to generate and order transactions to send to memory device 140. From one perspective, the primary function of memory controller 120 could be said to schedule memory access and other transactions to memory device 140. Such scheduling can include generating the transactions themselves to implement the requests for data by processor 110 and to maintain integrity of the data (e.g., such as with commands related to refresh). Transactions can include one or more commands, and result in the transfer of commands or data or both over one or multiple timing cycles such as clock cycles or unit intervals. Transactions can be for access such as read or write or related commands or a combination, and other transactions can include memory management commands for configuration, settings, data integrity, or other commands or a combination.

Memory controller 120 typically includes logic such as scheduler 130 to allow selection and ordering of transactions to improve performance of system 100. Thus, memory controller 120 can select which of the outstanding transactions should be sent to memory device 140 in which order, which is typically achieved with logic much more complex that a simple first-in first-out algorithm. Memory controller 120 manages the transmission of the transactions to memory device 140, and manages the timing associated with the transaction. In one example, transactions have deterministic timing, which can be managed by memory controller 120 and used in determining how to schedule the transactions with scheduler 130.

In one example, memory controller 120 includes refresh (REF) logic 126. Refresh logic 126 can be used for memory resources that are volatile and need to be refreshed to retain a deterministic state. In one example, refresh logic 126 indicates a location for refresh, and a type of refresh to perform. Refresh logic 126 can trigger self-refresh within memory device 140, or execute external refreshes which can be referred to as auto refresh commands) by sending refresh commands, or a combination. In one example, controller 150 within memory device 140 includes refresh logic 154 to apply refresh within memory device 140. In one example, refresh logic 154 generates internal operations to perform refresh in accordance with an external refresh received from memory controller 120. Refresh logic 154 can determine if a refresh is directed to memory device 140, and what memory resources 160 to refresh in response to the command.

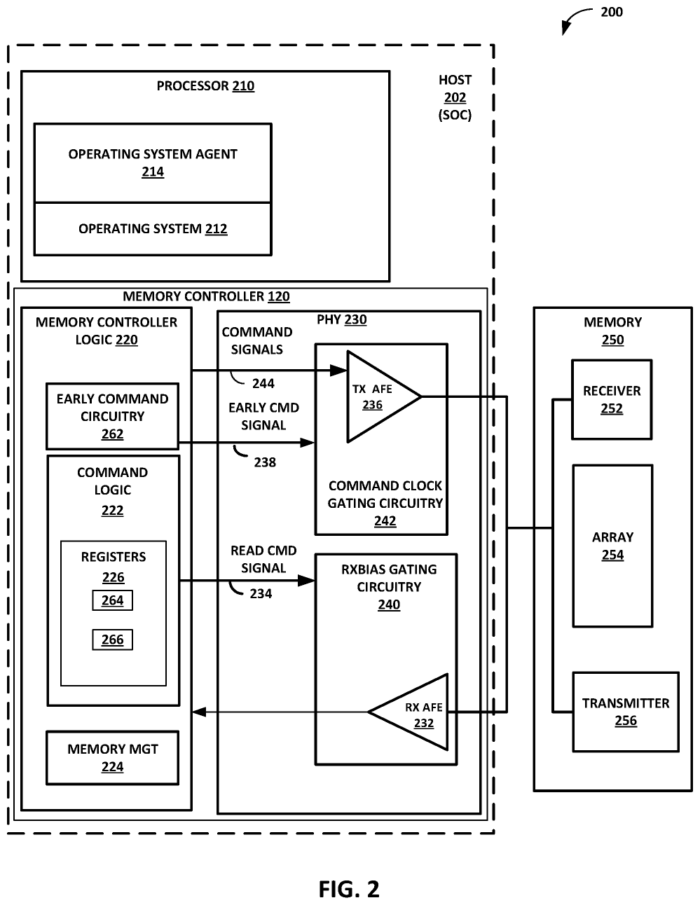

FIG. 2 is a block diagram of an example of a system in which memory power consumption is reduced in the memory PHY without increasing latency of memory read access. System 200 includes host 202, which represents the host hardware platform to which memory 250 is coupled. In one example, host 202 represents a system on a chip (SOC), which includes at least a host processor (processor 210) and a memory controller 120 (memory controller circuit).

Processor 210 represents the host processor. Processor 210 can be or include a single core or multicore processor. In one example, processor 210 represents a CPU (central processing unit). In one example, processor 210 represents a GPU (graphics processing unit). Processor 210 executes operating system 212, which provides a software platform to execute programs to generate requests for memory access. Operating system agent 214 represents a program or service that operates on operating system 212. Memory 250 can be or include one or multiple memory devices. Memory 250 includes array 254, which represents one or more arrays of memory cells or bit cells. Array 254 is arranged as rows of memory. Memory 250 also includes receiver 252 to receive commands from a PHY 230 in the host 202 and a transmitter 256 to transmit to drive signal lines to the PHY 230 in the host 202.

Memory 250 can be a volatile memory. Volatile memory is memory whose state (and therefore the data stored in it) is indeterminate if power is interrupted to the device. Dynamic volatile memory requires refreshing the data stored in the device to maintain state. One example of dynamic volatile memory includes DRAM (Dynamic Random Access Memory), or some variant such as Synchronous DRAM (SDRAM). A memory subsystem as described herein may be compatible with a number of memory technologies, such as DDR3 (Double Data Rate version 3) JESD79-3F, originally published by JEDEC (Joint Electronic Device Engineering Council) in June 2007. DDR4 (DDR version 4), JESD209-4D, originally published in September 2012, DDR5 (DDR version 5), JESD79-5B, originally published in June 2021, DDR6 (DDR version 6), currently in discussion by JEDEC, LPDDR3 (Low Power DDR version 3, JESD209-3C, originally published in August 2015, LPDDR4 (LPDDR version 4, JESD209-4D, originally published in June 2021), LPDDR5 (LPDDR version 5, JESD209-5B, originally published in June 2021), WIO2 (Wide Input/Output version 2), JESD229-2, originally published in August 2014, HBM (High Bandwidth Memory), JESD235B, originally published in December 2018, HBM2 (HBM version 2, JESD235D, originally published in March 2021, HBM3 (HBM version 3), JESD238A originally published in January 2023) or HBM4 (HBM version 4), currently in discussion by JEDEC, or others or combinations of memory technologies, and technologies based on derivatives or extensions of such specifications.

Memory controller 120 represents a controller to manage access to memory 250. In one example, memory controller 120 is part of processor 210, such as an integrated memory controller circuit. Memory controller 120 includes memory controller logic 220 that includes command logic 222 to generate memory access commands. The memory access commands can include a memory read command and a memory write command in response to requests from applications executing within or under operating system 212. The operating system 212 is software that manages computer hardware and software including memory allocation and access to I/O devices. Examples of operating systems include Microsoft® Windows®, Linux®, iOS® and Android®.

The memory controller logic 220 also includes early command circuitry 262 to generate an early command signal 238. The early command circuitry 262 collects early command information within the memory controller logic 220 to generate the early command signal 238. For example, the early command information can be whether a command will be sent in a subsequent clock cycle. Circuity in the memory controller 120 (for example, circuitry to generate commands or circuitry to pass through commands (for example, read/write command requests received by the memory controller 120)) process and send commands out of the memory controller 120 after the early command circuitry 262 has sent the early command signal 238.

Host 202 includes PHY (physical interface) 230. PHY 230 represents hardware interface components (circuitry) to drive command and address information to memory 250 to send the commands generated by command logic 222 to memory 250. In one example, PHY 230 represents a memory interface compatible with a DFI (DDR (double data rate) PHY interface). PHY 230 can be referred to as a memory controller physical interface to couple to memory 250. DFI is an interface protocol that defines the signals, timing parameters, and programmable parameters required to transfer control information and data across the DFI, and between the memory controller logic 220 and the PHY 230. The programmable parameters are options defined by the memory controller logic 220, PHY 230, or system 200 and programmed into the memory controller logic 220 and/or the PHY 230.

PHY 230 includes command clock gating circuitry 242 and receiver bias gating circuitry 240 (RXBias gating circuitry 240). The command clock gating circuitry 242 includes a Transmitter Analog Front End (TX AFE) 236. The TX AFE 236 represents transmitter hardware (circuitry) to drive command signals 244 received from the memory controller logic 220 to the receiver 252 in memory 250. The RXbias gating circuitry 240 includes a Receiver Analog Front End (RX AFE) 232. The RX AFE 232 represents receiver hardware (circuitry) to receive signal lines driven by transmitter 256 in memory 250.

System 200 illustrates the early command signal 238 generated by early command circuitry 262, to control the TX AFE 236 in command clock gating circuitry 242. System 200 illustrates the read command signal 234 that is generated by command logic 222 to control the RX AFE 232 in RXBias gating circuitry 240.

The command logic 222 includes hardware registers 226. Hardware registers 226 include a disable early command signal register 264 and a disable read command signal register 266. The disable early command signal register 264 to disable assertion of the early command signal 238. The disable read command signal register 266 to disable assertion of the read command signal 234.

In an embodiment, the disable early command signal register 264 is a register with one bit that is set to logic ‘1’ to disable the early command signal 238. While disabled, the early command signal 238 is set to logic ‘0’. While the early command signal register 264 is enabled (set to logic ‘0’), the early command signal is asserted (set to logic ‘1’) one clock period prior to a command on the command signals 244 (also referred to as command signal lines).

In an embodiment, the disable read command signal register 266 is a register with one bit that is set to logic ‘1’ to disable the read command signal 234. While disabled, the read command signal 234 is set to logic ‘0’. While the disable read command signal register 266 is enabled (set to logic ‘0’), the read command signal 234 is asserted (set to logic ‘1’) synchronously with a read command on the command signals 244.

Memory management (MGT) 224 in the memory controller logic 220 represents circuitry in memory controller logic 220 to manage the refresh of rows of array 254 in memory 250. When memory 250 enters self-refresh mode and exits self-refresh mode, there is a handoff between memory management 224 and memory 250. Such a handoff can be standards-based, based on the timing of when memory controller logic 220 sends commands to memory 250.

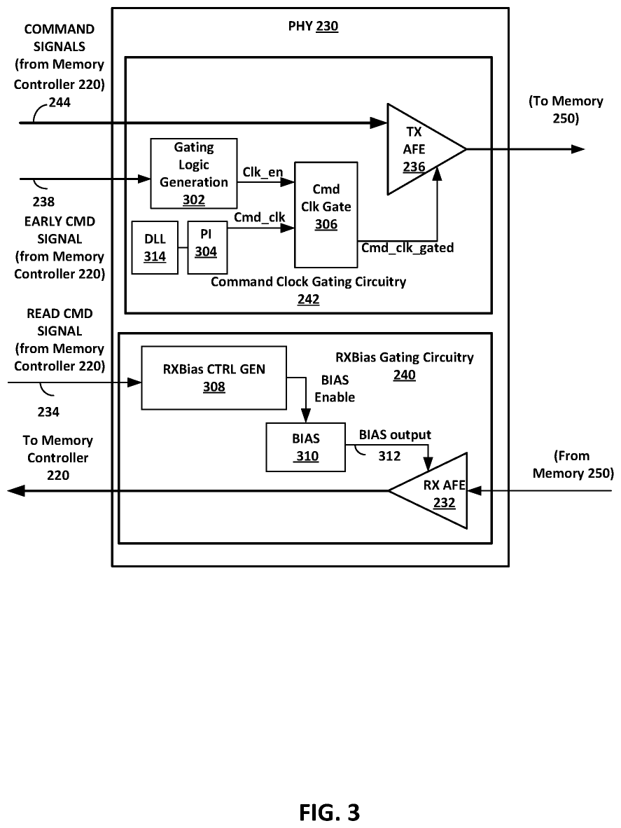

FIG. 3 is a block diagram of an example of the command clock gating circuitry 242 and the RXBias gating circuitry 240 in the PHY 230. The PHY 230 represents a physical interface that couples the memory 250 to the memory controller 120.

The PHY 230 is a mixed signal PHY. A mixed signal PHY can receive/transmit both analog signals and digital signals. The PHY 230 has two major power consumption components, dynamic power used by command clock gating circuitry 242 that scales with the frequency of operation and static constant/bias power used by the RXBias gating circuitry 240 in the PHY 230 that does not scale with data rate. Power use by the PHY 230 is reduced when the PHY 230 is idle by disabling a transmitter (TX AFE 236) in the command clock gating circuitry 242 and a receiver (RX AFE 232) in the RXBias gating circuitry 240.

The memory controller 120 monitors memory access requests. The memory access requests monitored by the memory controller 120 can be memory access commands received from the processor 210 or memory access commands generated internally in the memory controller 120 (for example, mode register read commands sent to memory 250 to read status registers in the memory 250). The monitored memory access requests represent the amount of memory traffic to/from the memory 250. The memory controller 120 uses an early command signal 238 and a read command signal 234 to communicate with the PHY 230 based on the amount of memory traffic to/from the memory 250. When the early command signal 238 and the read command signal 234 signals indicate a lack of commands from the memory controller 120 or a lack of read commands, power is saved in the PHY 230 by stopping the cmd_clk from running and reducing the electrical current output on Bias output 312 by bias circuitry 310 to 0. The cmd_clk is stopped from running (set to logic ‘0’) by turning the command clock gating circuitry 242 and the RXBias (Receiver Bias) gating circuitry 240 off.

The memory controller 220 asserts (sets to logic ‘1) the early command signal 238 (also referred to as an early command indication signal) when the memory controller 120 has a high confidence that a command (for example, read/write command, precharge (PRE) command, refresh (REF) command, mode register read (MRR) command) will be sent from the memory controller 120 to the PHY 230 to enable the transmitter in the command clock gating circuitry 242. For example, the memory controller 120 can have a high confidence that a command will be sent because commands that were ready to be sent by the memory controller 120 but due to scheduling tradeoffs made later in the decision pipeline or due to error recovery flows where commands were dropped prior to sending the commands to the PHY have not yet been sent.

Idle power savings while the TX AFE 236 in command clock gating circuitry 242 is disabled by cmd_clk_gated for 20% memory bandwidth using a 2:1 read to write data pattern is about 1.2 Watts. Idle power savings while the RX AFE 232 in the RXBias gating circuitry 240 is disabled for 20% memory bandwidth using a read to write data pattern ratio of 2:1 is about 1.05 Watts.

The command clock gating circuitry 242 includes a DLL (delay locked loop) 314 and a PI (phase interpolator) 304. The DLL 314 and PI 304 represent frequency and phase circuitry to generate a command clock (cmd_clk) output from the PI 304 that is input to a cmd clk gate 306. The DLL 314 and PI 304 receive a clock signal from a Phase Locked Loop (PLL). The TX AFE 236 represents a transmitter to transmit command signals 244 received from the memory controller 120 to the memory 250. The command signals 244 can include a chip select (CS) signal, a clock (CLK) signal (transmitted from the host CPU 202 to the memory 250), and command and address (CA[6:0]) signals. It will be understood that while the command and address (CA[6:0]) signals are illustrated as having 7 bits, other implementations can vary.

Gating logic generation circuitry 302 receives an early cmd (early command) signal 238 from early command circuitry 262 in the memory controller logic 220 and outputs a Clk_en (clock enable) signal that is received by cmd clk gate (command clock gate) circuitry 306. The state of the Cmd_clk_gated (command clock gated) signal output from cmd clk gate circuitry 306 is used to control output of the command signals 244 received from the memory controller logic 220 at the input of the TX AFE 236 to memory 250.

The RXBias gating circuitry 240 includes RXBias CTL GEN (Receive Bias control generation) circuitry 308, bias circuitry 310 and the RX AFE 232. The bias circuitry 310 generates direct current (DC) voltages and/or currents used by the RX AFE 232. The RX AFE 232 receives analog memory data from memory 250, samples the received analog memory data and sends the sampled received analog memory data to the memory controller 120.

Memory power consumption is reduced without increasing latency of memory read access. When inactive, power consumption is reduced in the PHY 230 by turning the receiver bias gating circuitry 242 off and turning off the Cmd_clock with an early command signal 238. The bias output 312 to the Rx AFE 232 and the Cmd_clk_gate signal to the TX AFE 236 are turned off, thereby reducing power consumption in the PHY 230).

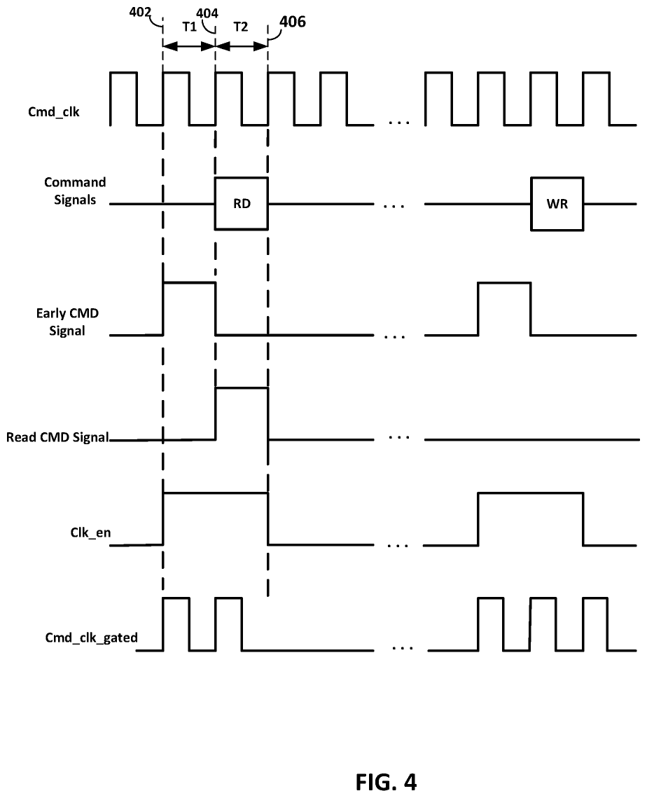

FIG. 4 is a timing diagram illustrating the operation of the command clock gating circuitry 242 and the RXBias gating circuitry 240 in the PHY 230.

At time 402, the early command circuitry 242 in the memory controller logic 220 asserts (sets to logic ‘1’) the early command signal 238 for one clock period T1 of the Cmd_clk for every command. The gating logic generation circuitry 302 asserts (sets to logic ‘1’) the clk_en signal output by the gating logic generation circuitry 302 in response to the assertion of the early command signal 238 received from the memory controller logic 220.

At time 404, a read command is transmitted by the memory controller 120 on command signals 244 and the command logic 222 in the memory controller logic 220 asserts (sets to logic ‘1’) the read command signal 234 for one clock period T2 of the Cmd_clk. The early command signal 234 is deasserted (set to logic ‘0’). The RXBias control generation circuitry 308 asserts the BIAS enable signal to enable BIAS circuitry to assert the BIAS output signal 312 to enable the RX AFE to receive data read from memory 250.

The clk_en signal is asserted (set to logic ‘1’) during clock period T1 and clock period T2 allowing the Cmd_Clk output by the PI 304 through the cmd clock gate circuitry 306 to output the cmd_clk_gate signal. The cmd_clk_gated signal is input to the TX AFE 236 to enable the transmission of command signals 244 received at the input of the TX AFE 236 from the TX AFE 236 to memory 250.

At time 406, clk_en is de-asserted (set to logic ‘0’).

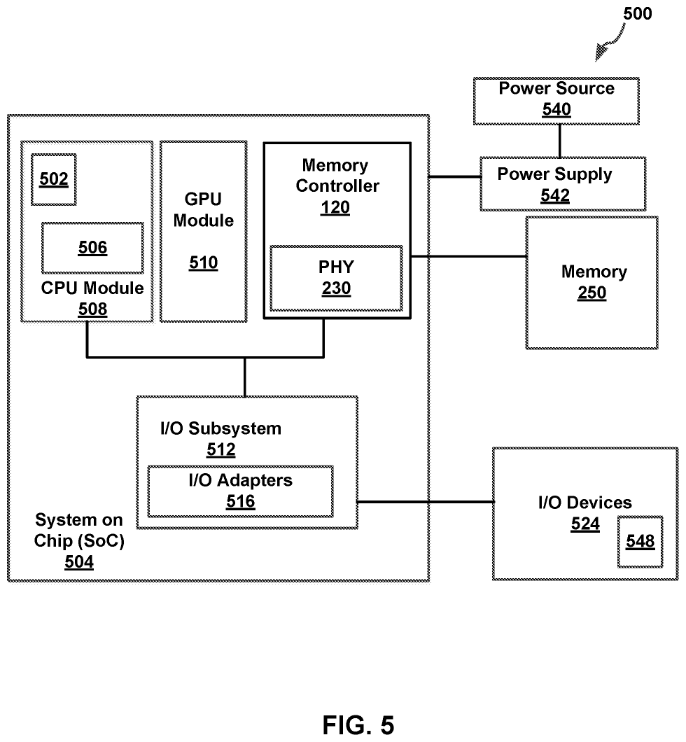

FIG. 5 is a block diagram of an embodiment of a computer system 500 that includes PHY 230. Computer system 500 can correspond to a computing device including, but not limited to, a server, a workstation computer, a desktop computer, a laptop computer, and/or a tablet computer.

The computer system 500 includes a system on chip (SOC or SoC) 504 which combines processor, graphics, memory, and Input/Output (I/O) control logic into one SoC package. The SoC 504 includes at least one Central Processing Unit (CPU) module 508, memory controller 120, and a Graphics Processor Unit (GPU) 510. In other embodiments, the memory controller 120 can be external to the SoC 504. The CPU module 508 includes at least one processor core 502 and a level 2 (L2) cache 506. The memory controller 120 is communicatively coupled to memory 250.

Although not shown, each of the processor core(s) 502 can internally include one or more instruction/data caches, execution units, prefetch buffers, instruction queues, branch address calculation units, instruction decoders, floating point units, retirement units, etc. The CPU module 508 can correspond to a single core or a multi-core general purpose processor, such as those provided by Intel® Corporation, according to one embodiment.

The Graphics Processor Unit (GPU) 510 can include one or more GPU cores and a GPU cache which can store graphics related data for the GPU core. The GPU core can internally include one or more execution units and one or more instruction and data caches. Additionally, the Graphics Processor Unit (GPU) 510 can contain other graphics logic units that are not shown in FIG. 5, such as one or more vertex processing units, rasterization units, media processing units, and codecs.

Within the I/O subsystem 512, one or more I/O adapter(s) 516 are present to translate a host communication protocol utilized within the processor core(s) 502 to a protocol compatible with particular I/O devices. Some of the protocols that adapters can be utilized for translation include Peripheral Component Interconnect (PCI)-Express (PCIe); Universal Serial Bus (USB); Serial Advanced Technology Attachment (SATA) and Institute of Electrical and Electronics Engineers (IEEE) 1594 “Firewire”.

The I/O adapter(s) 516 can communicate with external I/O devices 524 which can include, for example, user interface device(s) including a display and/or a touch-screen display 548, printer, keypad, keyboard, communication logic, wired and/or wireless, storage device(s) including hard disk drives (“HDD”), solid-state drives (“SSD”), removable storage media, Digital Video Disk (DVD) drive, Compact Disk (CD) drive, Redundant Array of Independent Disks (RAID), tape drive or other storage device. The storage devices can be communicatively and/or physically coupled together through one or more buses using one or more of a variety of protocols including, but not limited to, SAS (Serial Attached SCSI (Small Computer System Interface)), PCIe (Peripheral Component Interconnect Express), NVMe (NVM Express) over PCIe (Peripheral Component Interconnect Express), and SATA (Serial ATA (Advanced Technology Attachment)).

Additionally, there can be one or more wireless protocol I/O adapters. Examples of wireless protocols, among others, are used in personal area networks, such as IEEE 802.15 and Bluetooth, 4.0; wireless local area networks, such as IEEE 802.11-based wireless protocols; and cellular protocols.

Power source 540 provides power to the components of system 500. More specifically, power source 540 typically interfaces to one or multiple power supplies 542 in system 500 to provide power to the components of system 500. In one example, power supply 542 includes an AC to DC (alternating current to direct current) adapter to plug into a wall outlet. Such AC power can be renewable energy (e.g., solar power) power source 540. In one example, power source 540 includes a DC power source, such as an external AC to DC converter. In one example, power source 540 or power supply 542 includes wireless charging hardware to charge via proximity to a charging field. In one example, power source 540 can include an internal battery or fuel cell source.

Flow diagrams as illustrated herein provide examples of sequences of various process actions. The flow diagrams can indicate operations to be executed by a software or firmware routine, as well as physical operations. In one embodiment, a flow diagram can illustrate the state of a finite state machine (FSM), which can be implemented in hardware and/or software. Although shown in a particular sequence or order, unless otherwise specified, the order of the actions can be modified. Thus, the illustrated embodiments should be understood as an example, and the process can be performed in a different order, and some actions can be performed in parallel. Additionally, one or more actions can be omitted in various embodiments; thus, not all actions are required in every embodiment. Other process flows are possible.

To the extent various operations or functions are described herein, they can be described or defined as software code, instructions, configuration, and/or data. The content can be directly executable (“object” or “executable” form), source code, or difference code (“delta” or “patch” code). The software content of the embodiments described herein can be provided via an article of manufacture with the content stored thereon, or via a method of operating a communication interface to send data via the communication interface. A machine readable storage medium can cause a machine to perform the functions or operations described, and includes any mechanism that stores information in a form accessible by a machine (e.g., computing device, electronic system, etc.), such as recordable/non-recordable media (e.g., read only memory (ROM), random access memory (RAM), magnetic disk storage media, optical storage media, flash memory devices, etc.). A communication interface includes any mechanism that interfaces to any of a hardwired, wireless, optical, etc., medium to communicate to another device, such as a memory bus interface, a processor bus interface, an Internet connection, a disk controller, etc. The communication interface can be configured by providing configuration parameters and/or sending signals to prepare the communication interface to provide a data signal describing the software content. The communication interface can be accessed via one or more commands or signals sent to the communication interface.

Various components described herein can be a means for performing the operations or functions described. Each component described herein includes software, hardware, or a combination of these. The components can be implemented as software modules, hardware modules, special-purpose hardware (e.g., application specific hardware, application specific integrated circuits (ASICs), digital signal processors (DSPs), etc.), embedded controllers, hardwired circuitry, etc.

Besides what is described herein, various modifications can be made to the disclosed embodiments and implementations of the invention without departing from their scope.

Therefore, the illustrations and examples herein should be construed in an illustrative, and not a restrictive sense. The scope of the invention should be measured solely by reference to the claims that follow.

What is claimed is:

1. A memory controller comprising:
memory controller logic; and
a physical interface (PHY) to a memory, the PHY comprising:
command clock gating circuitry, the command clock gating circuitry including a transmitter to transmit command signals received from the memory controller logic to the memory; and
receiver bias gating circuitry, the receiver bias gating circuitry including a receiver to receive signal lines driven by the memory, the transmitter enabled via assertion of an early command signal received from the memory controller, the receiver enabled via a read command signal asserted by the memory controller logic, the early command signal asserted prior to the assertion of the read command signal.

2. The memory controller of claim 1, wherein the early command signal is asserted one clock period prior to the assertion of the read command signal, by the memory controller logic.

3. The memory controller of claim 2, wherein the early command signal is asserted by setting the early command signal to logic ‘1’.

4. The memory controller of claim 1, wherein the memory includes one or more memory devices.

5. The memory controller of claim 1, wherein the memory is a Dynamic Random Access Memory.

6. The memory controller of claim 1, wherein the memory controller logic includes a disable early command signal register to disable assertion of the early command signal.

7. The memory controller of claim 1, wherein the memory controller logic includes a disable read command signal register to disable assertion of the read command signal.

8. The memory controller of claim 1, wherein the transmitter is a Transmitter Analog Front End (TX AFE) and the receiver is a Receiver Analog Front End (RX AFE).

9. A system comprising:
a memory; and
a memory controller communicatively coupled to the memory, the memory controller comprising:
memory controller logic; and
a physical interface (PHY) to the memory, the PHY comprising:
command clock gating circuitry, the command clock gating circuitry including a transmitter to transmit command signals received from the memory controller logic to the memory; and
receiver bias gating circuitry, the receiver bias gating circuitry including a receiver to receive signal lines driven by the memory, the transmitter enabled via assertion of an early command signal received from the memory controller, the receiver enabled via a read command signal asserted by the memory controller logic, the early command signal asserted prior to the assertion of the read command signal.

10. The system of claim 9, wherein the early command signal is asserted one clock period prior to the assertion of the read command signal, by the memory controller logic.

11. The system of claim 10, wherein the early command signal is asserted by setting the early command signal to logic ‘1’.

12. The system of claim 9, wherein the memory includes one or more memory devices.

13. The system of claim 9, wherein the memory is a Dynamic Random Access Memory.

14. The system of claim 9, wherein the memory controller logic includes a disable early command signal register to disable assertion of the early command signal.

15. The system of claim 9, wherein the memory controller logic includes a disable read command signal register to disable assertion of the read command signal.

16. The system of claim 9, wherein the transmitter is a Transmitter Analog Front End (TX AFE) and the receiver is a Receiver Analog Front End (RX AFE).

17. The system of claim 9, further comprising one or more of:
at least one processor communicatively coupled to the memory controller;
a display communicatively coupled to at least one processor; or
a power supply to provide power to the system.

18. A method performed by a memory controller comprising:
enabling a transmitter in command clock gating circuitry in a PHY via an early command signal received from a memory controller logic; and
receiving, by receiver bias gating circuitry in a physical interface (PHY) in the memory controller logic to a memory, receive signal lines driven by the memory, the receiver enabled via a read command signal asserted by the memory controller logic, the early command signal asserted prior to assertion of the read command signal.

19. The method of claim 18, wherein the early command signal is asserted one clock period prior to the assertion of the read command signal, by the memory controller logic.

20. The method of claim 19, wherein the early command signal is asserted by setting the early command signal to logic ‘1’.
